(19) United States
(12) Patent Application Publication
(10) Pub. No.: US 2011/0204498 A1
(43) Pub. Date: Aug. 25, 2011

(54) LEAD FRAME AND SEMICONDUCTOR PACKAGE MANUFACTURED THEREWITH

(75) Inventors: Yin Kheng Au, Petaling Jaya (MY); Mohd Rusli Ibrahim, Shah Alam (MY); Meng Kong Lye, Shah Alam (MY); Zi Song Poh, Petaling Jaya (MY); Seng Kiong Teng, Kemuning Utama (MY); Kesyakumar V.C. Muniandy, Klang (MY)

(73) Assignee: FREESCALE SEMICONDUCTOR, INC, Austin, TX (US)

(21) Appl. No.: 12/712,159

(22) Filed: Feb. 24, 2010

(51) Int. Cl. H01L 23/495

(52) U.S. Cl. 257/670; 257/676; 257/E23.031; 257/E23.032

(57) ABSTRACT

A lead frame for a semiconductor package has a flag to which a semiconductor die is mounted. Tie bars are coupled to the flag. There is a first set of leads and each first set lead in the first set of leads has a first set lead parallel length and a first set lead tapered length. The first set lead parallel length of each first set lead has a constant width and edges that are parallel to edges of all other first set lead parallel lengths. A free end region of the first set lead tapered length of each first set lead provides a first set lead bond target region. There is a second set of leads disposed between a first one of the tie bars and the first set of leads. Each second set lead, in the second set of leads, has a second set lead parallel length and a second set lead tapered length. The second set lead parallel length of each second set lead has a constant width and edges that are parallel to edges of all other second set lead parallel lengths in the second set of leads and also parallel to the edges of first set lead parallel lengths. At least one second set lead has an extension length extending inwardly from the second set lead tapered length, the extension length has a constant width and provides a second set lead bond target region. Wire bond leads electrically couple both the first set lead bond target region and second set lead bond target region to respective die external electrical connection pads on a surface of the die and a package body encloses the die.

### BACKGROUND OF THE INVENTION

The present invention relates to lead frames and semiconductor packages. The present invention is particularly suited to lead frames and semiconductor packages associated with wire bonding of leads of the lead frame to external connection die pads of a semiconductor die.

Typical packaged semiconductors are formed with a semiconductor die mounted to a lead-frame. The lead-frame is formed from a sheet of metal that comprises a flag and tie bars attach the flag to an outer boundary of the frame. Each of the tie bars are bent so that the frame and flag are in different planes, this is often referred to as the flag being “down-set”.

Bond targets on leads of the lead-frame are wire bonded to external connection die pads to thereby provide a means of easily electrically connecting the die to circuit boards and the like. After the external connection die pads and bond targets are wire bonded, by bonding wires, the semiconductor die and pads are encapsulated (packaged) in a compound such as a plastics material leaving only sections of the leads exposed. These exposed leads are cut from the frame of the lead-frame (singulated) and bent for ease of connection to a circuit board.

It is well known that the number of transistors on a semiconductor die is continuously increasing. This increase results in greater die functionality and the need for more external connection die pads. The external connection die pads are generally disposed in along perimeter edges of the die and as their number increases problems can occur with wire bonding. Specifically, the width and density of the leads limit the proximity of the bond targets to the die pads. Accordingly, as the number of die pads increases the distance between the dies pads and bond targets also increases. As a result, longer bonding wires are required that may cause wire sweep, or wire shorting, especially for bonding wires that are bonded to bond targets near the ties bars where the bond wire length is typically the longest and space is lead space is limited due to the tie bars.

### BRIEF DESCRIPTION OF THE DRAWINGS

The invention, together with objects and advantages thereof, may best be understood by reference to the following description of preferred embodiments together with the accompanying drawings in which:

FIG. 1 is a plan view of a lead frame in accordance with a preferred embodiment of the present invention;

FIG. 2 is a plan view of a semiconductor package manufactured from the lead frame of FIG. 1;

FIG. 3 is a side view of the semiconductor package of FIG. 2;

FIG. 4 is a plan view of a lead frame in accordance with another preferred embodiment of the present invention; and

FIG. 5 is a plan view of a semiconductor package manufactured from the lead frame of FIG. 4.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practiced. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that system, circuit, device components and method steps that comprises a list of elements or steps does not include only those elements but may include other elements or steps not expressly listed or inherent to such system, circuit, device components or steps. An element or step proceeded by “comprises . . . a” does not, without more constraints, preclude the existence of additional identical elements or steps that comprises the element or step.

In one embodiment the present invention provides a lead frame comprising a lead frame flag and tie bars coupling the lead frame flag to an outer boundary of the lead frame. There is a first set of leads extending from the outer boundary towards the lead frame flag, each first set lead in the first set of leads has a first set lead parallel length adjacent the outer boundary and a first set lead tapered length extending inwardly from an end of the first set lead parallel length. The first set lead parallel length of each first set lead has a constant width and edges that are parallel to edges of all other first set lead parallel lengths in the first set of leads. A free end region of the first set lead tapered length, of each first set lead, provides a first set lead bond target region. There is a second set of leads disposed between a first one of the tie bars and the first set of leads. Each second set lead, in the second set of leads, has a second set lead parallel length adjacent the outer boundary and a second set lead tapered length extending inwardly from an end of the second set lead parallel length. The second set lead parallel length of each second set lead has a constant width and edges that are parallel to edges of all other second set lead parallel lengths in the second set of leads and also parallel to the edges of first set lead parallel lengths. At least one second set lead has an extension length extending inwardly from the second set lead tapered length, the extension length has a constant width and provides a second set lead bond target region.

In another embodiment the present invention provides a semiconductor package comprising a lead frame flag and a semiconductor die mounted to the lead frame flag. Tie bars are coupled to the lead frame flag and there is a first set of leads extending from an outer boundary of the semiconductor package towards the lead frame flag. Each first set lead in the first set of leads has a first set lead parallel length adjacent the outer boundary and a first set lead tapered length extending inwardly from an end of the first set lead parallel length. The first set lead parallel length of each first set lead has a constant width and edges that are parallel to edges of all other first set lead parallel lengths in the first set of leads. A free end region of the first set lead tapered length of each first set lead provides a first set lead bond target region. There is a second set of leads disposed between a first one of the tie bars and the first set of leads. Each second set lead, in the second set of leads, has a second set lead parallel length adjacent the outer boundary and a second set lead tapered length extending inwardly from an end of the second set lead parallel length. The second set lead parallel length of each second set lead has a constant width and edges that are parallel to edges of all other second set lead parallel lengths in the second set of leads and also parallel to the edges of first set lead parallel lengths. At least one second set lead has an extension length extending inwardly from the second set lead tapered length, the extension length has a constant width and providing a second set lead bond target region. Wire bond leads electrically couple both the first set lead bond target region and second set lead bond target region to respective die external electrical connection pads on a surface of the die and a package body encloses the die.

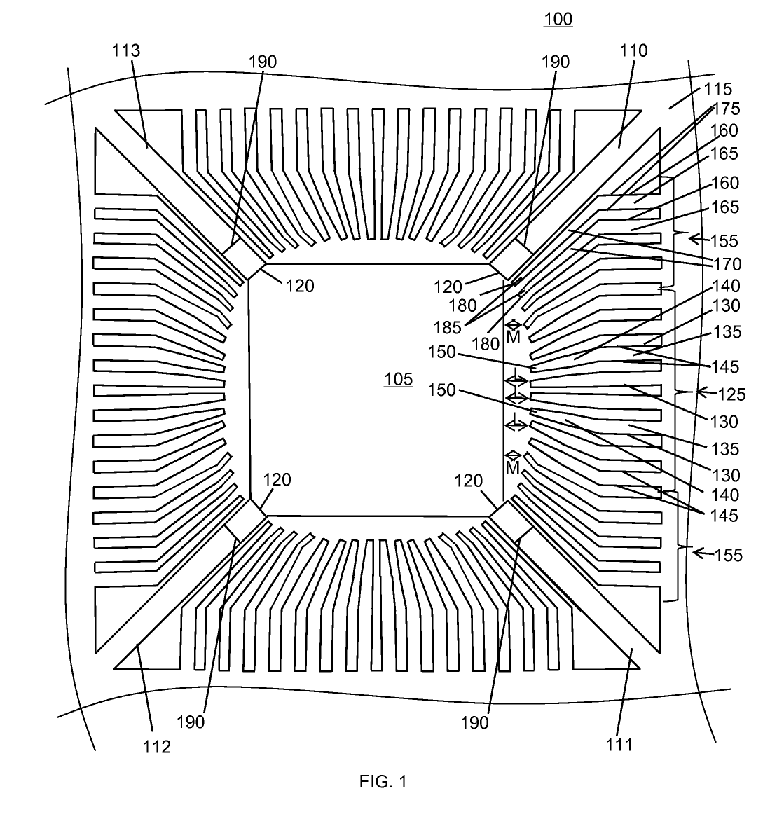

Referring to FIG. 1 there is illustrated a plan view of a lead frame 100 in accordance with a preferred embodiment of the present invention. The lead frame 100 includes a lead frame flag 105 and there are tie bars 110,111,112,113 coupling the lead frame flag 105 to an outer boundary 115 of the lead frame 100. More specifically, the lead frame flag 105 is typically substantially rectangular and the tie bars 110,111,112,113 extend from corner areas 120 of the lead frame flag 105. The lead frame 100 has a first set of leads 125 extending from the outer boundary 115 towards the lead frame flag 105. Each first set lead 130, in the first set of leads 125, has a first set lead parallel length 135 adjacent the outer boundary 115 and a first set lead tapered length 140 extending inwardly from an end of the first set lead parallel length 135. The first set lead parallel length 135 of each first set lead 130 has a constant width and edges that are parallel to edges of all other first set lead parallel lengths 135 in the first set of leads 125. Also, a free end region of the first set lead tapered length 140 of each first set lead 130 provides a first set lead bond target region 150.

There is a second set of leads 155 disposed between a first one of the tie bars 110 and the first set of leads 125. Each second set lead 160, in the second set of leads 155, has a second set lead parallel length 165 adjacent the outer boundary and a second set lead tapered length 170 extending inwardly from an end of the second set lead parallel length 165. The second set lead parallel length 165 of each second set lead 160 has a constant width and edges 175 that are parallel to edges 175 of all other second set lead parallel lengths 165 and also parallel to the edges 140 of the first set lead parallel lengths 135. Furthermore, at least one (and typically most or every) second set lead 160 has an extension length 180 extending inwardly from the tapered length 170. This extension length 180 has a constant width and provides a second set lead bond target region 185.

As illustrated, the second set lead bond target region 185 of each second set lead 160 is closer to the lead frame flag 105 than the first set lead bond target region 150 of each first set lead 125. Also, with the exception of the second set lead 160 that is immediately adjacent the first one of the tie bars 110, the extension length 180 is in a direction extending away from the first one of the tie bars 110 at an angle relative to the second set lead tapered length 170. In addition, the second set lead parallel length 165 of every second set lead 160 is at an angle relative to the second set lead tapered length 170. Similarly, the first set lead parallel length 135 of every first set lead 130 is at an angle relative to the first set lead tapered length 140.

In this embodiment, each first set lead bond target region 150 of each first set lead 130 are equidistant from the lead frame 105. The distance of each first set lead bond target region 150 is indicated by arrow line L. Also, a minimum wire bond distance, indicated by line M, between the lead frame 105 and second set lead bond target 185 differs for each second set lead 160. In this regard, the closer the second set lead 160 is to the first one of the tie bars 110 the smaller is the minimum respective bond target distance M.

It is clear from the illustration of FIG. 1 that there also another second set of leads 155 disposed between a second one of the tie bars 111 and the first set of leads 125. Also, there is another first set of leads 125 and two sets of the second set of leads 155 disposed between the second one of the tie bars 111 and a third one of the tie bars 112. Similarly, there is another first set of leads 125 and two sets of the second set of leads 155 disposed between the third one of the tie bars 112 and a fourth one of the tie bars 113. Finally, there is another first set of leads 125 and two sets of the second set of leads 155 disposed between the fourth one of the tie bars 112 and the first one of the tie bars 110. The lead frame flag 105 is “down-set” so that it is in a different (lower) plane than the first set of leads 125 and second set of leads 155. The lead frame flag 105 is “down-set” by a bend 190 in each of the in the tie bars 110, 111, 112, 113.

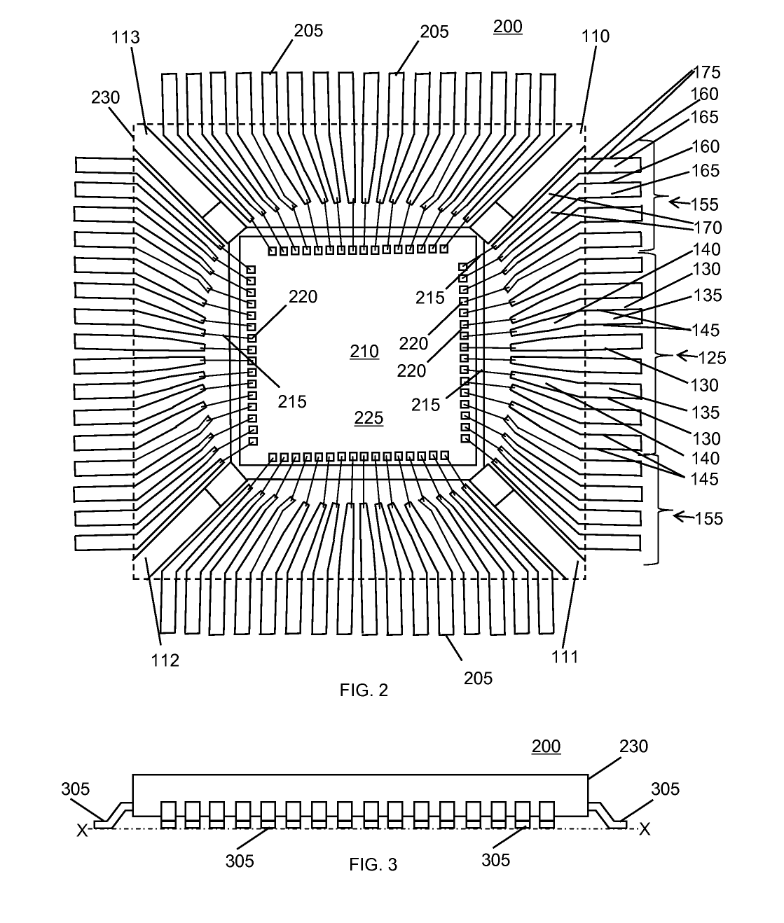

Referring to FIG. 2 there is illustrated a plan view of a semiconductor package 200. The semiconductor package 200 includes the lead frame 100 that has been singulated (cut away) from a surrounding integral metal sheet (typically copper) that provides the outer boundary 115. Hence, the outer boundary is now an outer boundary 205 of the semiconductor package 200 which is simply the outermost ends of the first and second set of leads 125, 155 and every first set lead 130 and every second set lead 160 is electrically separated from all other leads. It will therefore be apparent that the outer boundary 115 of the lead frame 100 and the outer boundary 205 of the semiconductor package 200 are interchangeable depending whether or not reference is being made to the lead frame 100 or semiconductor package 200. Also, the ties bars 110,111,112,113 are still coupled to the lead frame flag 105 but have been singulated and therefore electrically isolated from all leads of the first and second set of leads 125, 155.

The semiconductor package 200 includes a semiconductor die 210 mounted to the lead frame flag 105. There are wire bond leads 215 electrically coupling both the first set lead bond target region and second set lead bond target region to respective die external electrical connection pads 220 on a surface 225 of the die 210. In addition, there is a package body 230 (shown in phantom) enclosing the die 210, lead frame flag 105, wire bond leads 215, ties bars 110,111,112,113 and part of the first and second set of leads 125, 155. However, the majority of the parallel lengths 135 and 165 extend outside the package body.

Referring to FIG. 3 there is illustrated a side view of the semiconductor package 200. As shown, the parallel lengths 135 and 165 are bent to provide contact pads (feet) 305 that form a seating plane X.

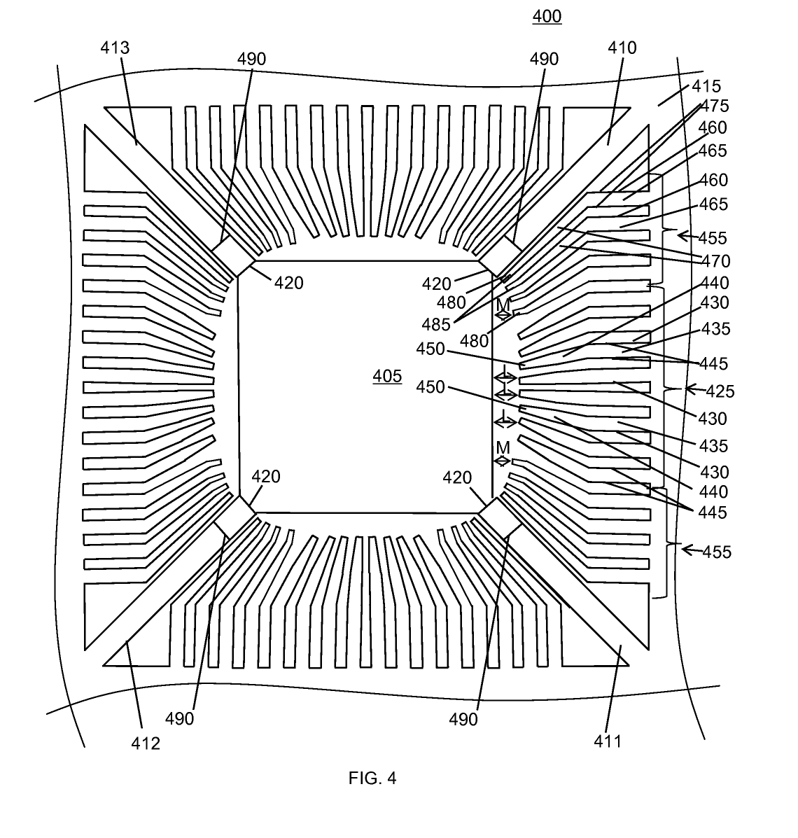

Referring to FIG. 4 there is illustrated a plan view of a lead frame 400 in accordance with another preferred embodiment of the present invention. The lead frame 400 includes a lead frame flag 405 and there are tie bars 410,411,412,413 coupling the lead frame flag 405 to an outer boundary 415 of the lead frame 400. More specifically, the lead frame flag 405 is typically substantially rectangular and the tie bars 410,411,412,413 extend from corner areas 420 of the lead frame flag 405. The lead frame 400 has a first set of leads 425 extending from the outer boundary 415 towards the lead frame flag 405. Each first set lead 430, in the first set of leads 425, has a first set lead parallel length 435 adjacent the outer boundary 415 and a first set lead tapered length 440 extending inwardly from an end of the first set lead parallel length 435. The first set lead parallel length 435 of each first set lead 430 has a constant width and edges that are parallel to edges of all other first set lead parallel lengths 435 in the first set of leads 425. Also, a free end region of the first set lead tapered length 440 of each first set lead 430 provides a first set lead bond target region 450.

There is a second set of leads 455 disposed between a first one of the tie bars 410 and the first set of leads 425. Each second set lead 460, in the second set of leads 455, has a second set lead parallel length 465 adjacent the outer boundary and a second set lead tapered length 470 extending inwardly from an end of the second set lead parallel length 465. The second set lead parallel length 465 of each second set lead 460 has a constant width and edges 475 that are parallel to edges 475 of all other second set lead parallel lengths 465 and also parallel to the edges 440 of the first set lead parallel lengths 435. Furthermore, at least one (and typically most or every) second set lead 460 has an extension length 480 extending inwardly from the tapered length 470. This extension length 480 has a constant width and provides a second set lead bond target region 485.

As illustrated, the second set lead bond target region 485 of each second set lead 460 is closer to the lead frame flag 405 than the first set lead bond target region 450 of each first set lead 425. Also, with the exception of the second set lead 460 that is immediately adjacent the first one of the tie bars 410, the extension length 480 is in a direction extending towards the first one of the tie bars 410 at an angle relative to the second set lead tapered length 470. In addition, the second set lead parallel length 465 of every second set lead 460 is at an angle relative to the second set lead tapered length 470. Similarly, the first set lead parallel length 435 of every first set lead 430 is at an angle relative to the first set lead tapered length 440.

In this embodiment, each first set lead bond target region 450 of each first set lead 430 are equidistant from the lead frame 405. The distance of each first set lead bond target region 450 is indicated by arrow line L. Also, a minimum wire bond distance, indicated by line M, between the lead frame 405 and second set lead bond target 485 differs for each second set lead 460. In this regard, the closer the second set lead 460 is to the first one of the tie bars 410 the smaller is the minimum respective bond target distance M.

As illustrated, there also another second set of leads 455 disposed between a second one of the tie bars 411 and the first set of leads 425. Also, there is another first set of leads 425 and two sets of the second set of leads 455 disposed between the second one of the tie bars 411 and a third one of the tie bars 412. Similarly, there is another first set of leads 425 and two sets of the second set of leads 455 disposed between the third one of the tie bars 412 and a fourth one of the tie bars 413. Also, there is yet a further first set of leads 425 and two sets of the second set of leads 455 disposed between the fourth one of the tie bars 412 and the first one of the tie bars 410.

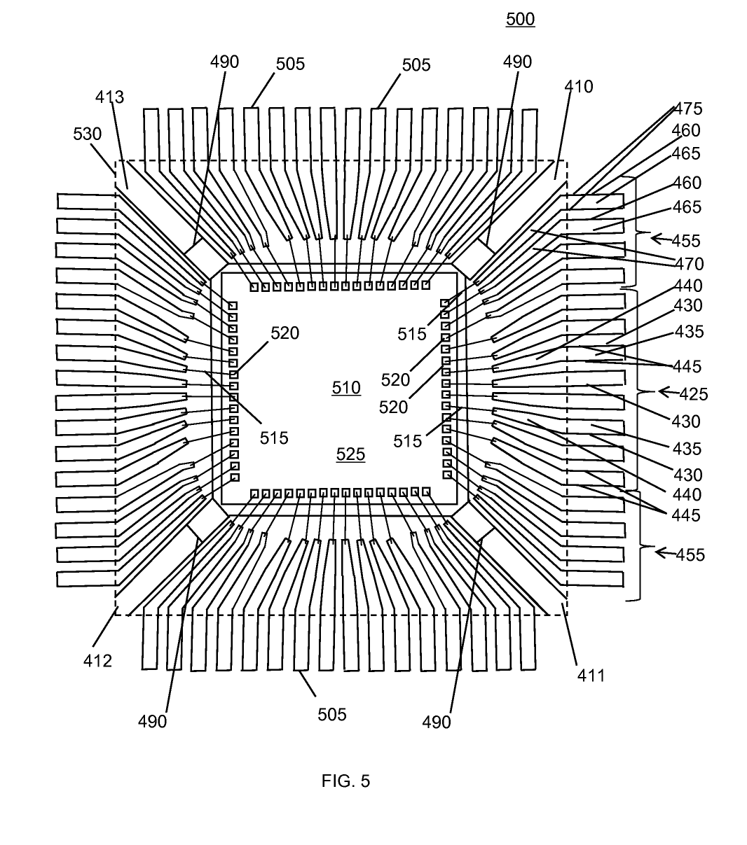

Referring to FIG. 5 there is illustrated a plan view of a semiconductor package 500. The semiconductor package 500 includes the lead frame 400 that has been singulated and the outer boundary is now an outer boundary 505 of the semiconductor package 500 which is simply the outermost ends of the first and second set of leads 425, 455. As a result of singulation, every first set lead 430 and every second set lead 460 is electrically separated from all other leads. It will therefore be apparent that the outer boundary 415 of the lead frame 400 and the outer boundary 505 of the semiconductor package 500 are interchangeable depending whether or not reference is being made to the lead frame 400 or semiconductor package 500. Also, the ties bars 410,411,412,413 are still coupled to the lead frame flag 405 but have been singulated and therefore electrically isolated from all leads of the first and second set of leads 425, 455.

The semiconductor package 500 includes a semiconductor die 510 mounted to the lead frame flag 405. There are wire bond leads 515 electrically coupling both the first set lead bond target region and second set lead bond target region to respective die external electrical connection pads 520 on a surface 525 of the die 510. In addition, there is a package body 530 (shown in phantom) enclosing the die 510, lead frame flag 405, wire bond leads 515, ties bars 410,411,412,413 and part of the first and second set of leads 425, 455. As above, the majority of the parallel lengths 435 and 465 extend outside the package body, these parallel lengths 435 and 465 are bent to provide contact pads (feet) 405 that form a seating plane.

Advantageously, the present invention alleviates the requirement of longer bonding wires and may reduce the possibility of wire sweep or wire shorting of bonding wires that are bonded to bond targets near the ties bars. These bond targets near the ties bars are provided by the second set lead bond target region 185 or 485 that are closer to the lead frame flag 405 than the first set lead bond target region 150 or 450. Also, the problem of limited lead space due to the tie bars is alleviated since the extension length 180 or 480 is in either a direction extending towards or away from the first one of the tie bars.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A lead frame comprising:
a lead frame flag;
tie bars coupling the lead frame flag to an outer boundary of the lead frame;
a first set of leads extending from the outer boundary towards the lead frame flag, each first set lead in the first set of leads having a first set lead parallel length adjacent the outer boundary and a first set lead tapered length extending inwardly from an end of the first set lead parallel length, the first set lead parallel length of each first set lead having a constant width and edges that are parallel to edges of all other first set lead parallel lengths in the first set of leads, wherein a free end region of the first set lead tapered length of each first set lead provides a first set lead bond target region; and
a second set of leads disposed between a first one of the tie bars and the first set of leads, each second set lead in the second set of leads having a second set lead parallel length adjacent the outer boundary and a second set lead tapered length extending inwardly from an end of the second set lead parallel length, the second set lead parallel length of each second set lead having a constant width and edges that are parallel to edges of all other second set lead parallel lengths in the second set of leads and also parallel to the edges of first set lead parallel lengths, wherein at least one second set lead has an extension length extending inwardly from the second set lead tapered length, the extension length having a constant width and providing a second set lead bond target region.

2. The lead frame of claim 1, wherein the second set lead bond target region of each second set lead is closer to the lead frame flag than the first set lead bond target region of each first set lead.

3. The lead frame of claim 2, wherein the extension length is in a direction extending away from the first one of the tie bars.

4. The lead frame of claim 3, wherein the extension length is at an angle relative to the second set lead tapered length.

5. The lead frame of claim 2, wherein the extension length is in a direction extending towards the first one of the tie bars.

6. The lead frame of claim 5, wherein the extension length is at an angle relative to the second set lead tapered length.

7. The lead frame of claim 2, wherein the second set lead parallel length is at an angle relative to the second set lead tapered length.

8. The lead frame of claim 2, wherein the first set lead parallel length is at an angle relative to the first set lead tapered length.

9. The lead frame of claim 2, wherein each first set lead bond target region of each first set lead are equidistant from the lead frame.

10. The lead frame of claim 2, wherein a minimum wire bond distance between the lead frame and second set lead bond target differs for each second set lead, wherein the closer the second set lead is to the first one of the tie bars the smaller is the minimum respective bond target distance.

11. A semiconductor package comprising:
a lead frame flag;
a semiconductor die mounted to the lead frame flag;
tie bars coupled to the lead frame flag;
a first set of leads extending from an outer boundary of the semiconductor package towards the lead frame flag, each first set lead in the first set of leads having a first set lead parallel length adjacent the outer boundary and a first set lead tapered length extending inwardly from an end of the first set lead parallel length, the first set lead parallel length of each first set lead having a constant width and edges that are parallel to edges of all other first set lead parallel lengths in the first set of leads, wherein a free end region of the first set lead tapered length of each first set lead provides a first set lead bond target region; and
a second set of leads disposed between a first one of the tie bars and the first set of leads, each second set lead in the second set of leads having a second set lead parallel length adjacent the outer boundary and a second set lead tapered length extending inwardly from an end of the second set lead parallel length, the second set lead parallel length of each second set lead having a constant width and edges that are parallel to edges of all other second set lead parallel lengths in the second set of leads and also parallel to the edges of first set lead parallel lengths, wherein at least one second set lead has an extension length extending inwardly from the second set lead tapered length, the extension length having a constant width and providing a second set lead bond target region;
wire bond leads electrically coupling both the first set lead bond target region and second set lead bond target region to respective die external electrical connection pads on a surface of the die; and
a package body enclosing the die.

12. The semiconductor package of claim 11, wherein the second set lead bond target region of each second set lead is closer to the lead frame flag than the first set lead bond target region of each first set lead.

13. The semiconductor package of claim 12, wherein the extension length is in a direction extending away from the first one of the tie bars.

14. The semiconductor package of claim 13, wherein the extension length is at an angle relative to the second set lead tapered length.

15. The semiconductor package of claim 12, wherein the extension length is in a direction extending towards the first one of the tie bars.

16. The semiconductor package of claim 15, wherein the extension length is at an angle relative to the second set lead tapered length.

17. The semiconductor package of claim 12, wherein the second set lead parallel length is at an angle relative to the second set lead tapered length.

18. The semiconductor package of claim 12, wherein the first set lead parallel length is at an angle relative to the first set lead tapered length.

19. The semiconductor package of claim 12, wherein each first set lead bond target region of each first set lead are equidistant from the lead frame.

20. The semiconductor package of claim 12, wherein a minimum wire bond distance between the lead frame and second set lead bond target differs for each second set lead, wherein the closer the second set lead is to the first one of the tie bars the smaller is the minimum respective bond target distance.
